(19) United States
(12) Patent Application Publication
(10) Pub. No.: US 2008/0193790 A1
(43) Pub. Date: Aug. 14, 2008

(54) Drum For a Machine Producing a Patterned Nonwoven and Obtained Fabric

(75) Inventor: Ludovic Leroy, Aix en Provence (FR)

Correspondence Address: PEARNE & GORDON LLP, 1801 EAST 9TH STREET, SUITE 1200, CLEVELAND, OH, 44114-3108, US

(73) Assignee: RIETER PERFOJET, Montbonnot, FR (FR)

(21) Appl. No.: 11/913,115

(22) PCT Filed: May 19, 2006
(86) PCT No.: PCT/FR06/01141

§ 371 Date: Oct. 30, 2007

(30) Foreign Application Priority Data
May 20, 2005 (FR) 0505087

(51) Int. Cl. B32B 3/10; G03F 7/00; D04H 13/00

(52) U.S. Cl. 428/596; 28/100; 430/324; 442/334

(57) ABSTRACT

The inventive nickel drum comprises a first part whose lateral surface is provided with perforations at the first level thereof and a second part whose lateral surface is provided with perforations at the second level different from the first level. Said invention can be used for producing nonwovens.

The invention relates to machines for producing patterned nonwoven textile products and to nonwovens produced by said machines.

In WO 03/008691, a cylinder for the embossed patterning of a nonwoven is described. The device used is such that it is impossible to create closed contours without using metal bridges linking the interior of the contour to the exterior thereof. The result necessarily is patterns defined by discontinuous lines. The invention sets out, on the other hand, to obtain a pattern defined by a continuous contour on a nonwoven.

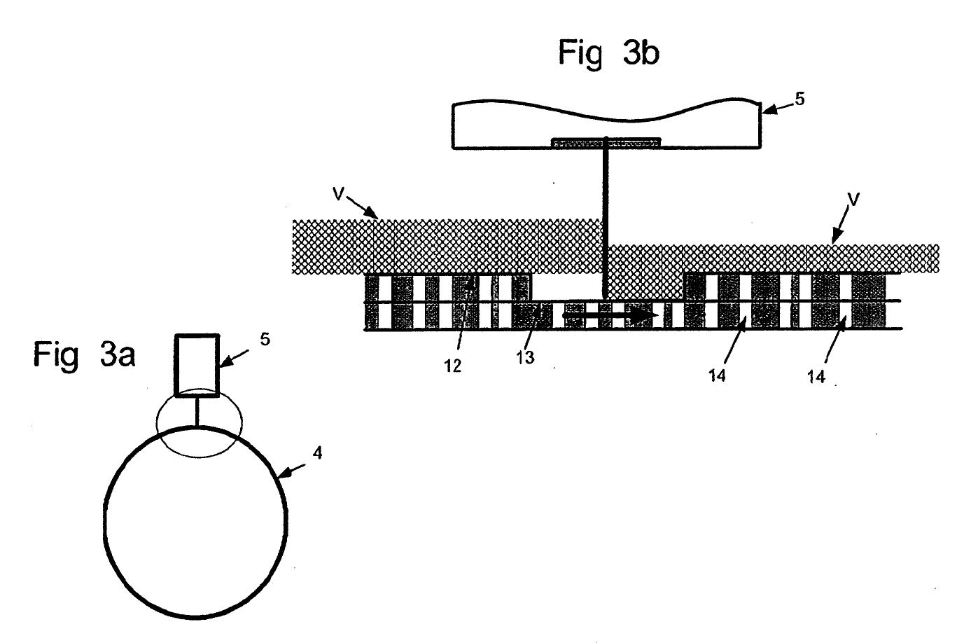

In U.S. Pat. No. 5,115,544, patterns are produced on a nonwoven by passing the nonwoven over a drum and spraying jets of water onto the nonwoven while it passes over the drum. Two scenarios are envisaged to produce intaglio patterns on the nonwoven. In both scenarios, there are limitations on the width of the line defining the pattern or on the width of the pattern either for technical reasons related directly to the drum, or for product-related reasons. In the case of the embossed cloth described in FIGS. 3, 4 and 5, the fineness of the design lines is limited in minimum terms by the distortion properties of the embossed nonwoven and limited in maximum terms by the fact that it is impossible to have a large embossed surface “in the air” with no mechanical support. In the case of an embossing produced by means of a full body, welded or bonded onto a porous cloth as indicated in FIGS. 7 to 10, said embossed zone being full, water drainage is not possible. The fibres are displaced around the solid by the water flow. A line width of more than 2 mm creates holes in the nonwoven because the fibre density is too low in said zone.

In EP 0 705 932 B2, a nonwoven is described which retains its three-dimensional structure even when it is subject to a constraint. FIGS. 13 and 14 describe a drum useful to this end. It is holed with craters with a conical orifice whereof it is explained that the angle 111 of the cone must be such that it does not follow that the outer surface of the lateral wall is flat and smooth. FIG. 14 show that the opening ratio of the outer surface of the lateral wall is very high.

In EP 0 776 391, a randomly micro-perforated roll is described.

The invention overcomes these drawbacks while resolving a different problem. It enables a nonwoven to be obtained with low levels of hairiness both in the projecting parts and in the intaglio parts defining the pattern, which may be with continuous contours and have a dimension of more than 2 mm. It is therefore possible to create patterns defined by an intentionally traced line, but also patterns that are not defined by a line traced by a groove or by a rib, but are in the form of a self-defining “one piece bloc”, projecting in its entirety or intaglio in its entirety.

The subject of the invention is a metal drum that has at a first level at least one first lateral wall zone provided with through perforations defined by first full parts and at least one second lateral wall zone provided with through perforations defined by second full parts at a second level different from the first level, characterised in that
the size of the perforations is between 0.1 and 1.2 mm,
the number of perforations both in the at least one first zone and in the at least one second zone is between 40 and 200 to the square centimetre, and
the opening ratio is between 3 and 60%, and preferably, between 5 and 15%.

The inventive drum has an open surface (small opening proportion). This characteristic means that the product produced by the invention has low levels of hairiness. The drum enables the bonding to be generated at the same time as the patterning. The free fibre ends (hairiness) are thereby limited in number since they are incorporated into the fibrous mass (interconnected fibres). Existing patterning technologies offer a large open surface that does not enable bonding to take place, which means that hairiness is increased during patterning.

The drum is preferably made of nickel, but it can also be made of another metal or alloy, and particularly copper.

The numbers of perforations, both in the at least one first zone and in the at least one second zone are preferably between 80 and 130 to the cm².

The patterns can only be effectively formed by an exact management of the water flow from the time it is emitted until it is sucked through the pattern forming drum. Managing water flow, particularly significant in the case of wetlaid products where the fibres are very short and therefore more mobile, is controlled through the distribution and dimension of the perforations.

In order to obtain good patterning without creating perforations in the nonwoven, these perforations have a dimension of between 0.1 and 1.2 mm and the density of said perforations must be between 40 and 200/cm².

If the dimension of the perforations is below 0.1 mm or the density below 40/cm², the drainage rate is locally inadequate, which may give rise to perforations caused by a too large displacement of the fibres.

If the size of the perforations is more than 1.2 mm, or the density more than 200/cm², the open surface is too large to retain the fibres which will then be drawn and sucked up with the water, thereby creating uncontrolled perforations in the nonwoven.

Below a comparative example is given showing the decisive nature of the dimensions of the perforations:
A wetlaid nonwoven comprising 80% cellulose fibre and 20% polyester fibre with a mass per unit area of 40 g/m² is embossed using the cylinder. The cylinder has a pattern imitating a woven textile appearance in the form of chevrons. The cylinder is fitted with perforations 0.5 mm in diameter and with a perforation density of 10/cm². After patterning on the cylinder, the nonwoven has in addition to the chevron pattern perforations of random size and position due to poor water drainage during treatment.
A wetlaid nonwoven comprising 80% cellulose fibres and 20% polyester fibres with a mass per unit area of 40 g/m² is embossed using the cylinder. The cylinder has a pattern imitating a woven textile appearance in the form of chevrons. The cylinder is fitted with perforations 0.3 mm in diameter and with a perforation density of 100/cm². After patterning on the cylinder, the nonwoven has a chevron pattern and a uniform surface condition.

The through perforations have a dimension of preferably between 0.3 and 0.8 mm. Perforation dimension is taken to mean the diameter of the circumscribed circle of a perforation. The perforation may assume any shape and in particular be circular, rectangular, or elliptical. The perforations are preferably distributed randomly on the lateral surface of the cylinder. The surface of each perforation may be between 0.008 and 1.5 mm². The opening ratio is between 3 and 60% and preferably between 5 and 15%, said percentage constituting the perforated surface relative to the total lateral surface of the cylinder.

Preferably, the perforations are cylindrical preferably with a circular transverse cross-section, although they may also have a square or other cross-section. The surface area covered by one perforation on the outer lateral surface of the cylinder is thus equal to the surface area covered by this perforation on the inner lateral surface of the cylinder.

Preferably, the first layer is between 0.3 and 2 mm thick and the second layer is between 0.3 and 2 mm thick.

Generally speaking, there are several first zones which are all at the same first level and several second zones which are all at the same second level. It is better, in order to obtain good patterning results on the nonwoven, for the smallest imaginary inscribed circle traced on the outer face of the lateral surface of the cylinder, both in the at least one first zone and in the least one second zone, to be more than 0.5 mm in diameter, and preferably more than 2 mm.

If, for example, a first zone is in the form of a hammer, this means that the smallest inscribed circle is the one which corresponds to the handle of the hammer and not to a circle inscribed in the head of the hammer.

According to a much preferred embodiment, the variation in the height of the outer surface of a zone, and preferably of all lateral wall zones, is less than 0.05 and better than 0.01 mm. This is in direct contradiction with the teaching of EP 0 705 932B. This enables a surface to be obtained which is less aggressive relative to the fibres since it promotes hydro-bonding, which gives the nonwoven a more regular appearance.

A level is defined by points at the same radial distance from the drum axis. All points at one and the same level are on the lateral face of one and the same cylinder of a given diameter. The heights of the outer surface of a zone are defined in the same way.

The variation in height is measured in accordance with ISO standard 4287 where it is indicated by the notation zt. The stylus instrument from the Federal Office for Metrology METAS is used.

The measuring instrument is a stylus instrument with a precisely benchmarked translatory motion unit. The movement of the stylus arm is measured interferometrically. The vertical resolution is 10 nm at each measurement point. The horizontal displacement resolution is 0.25 μm. The measuring range for profile evaluation extends over 120 mm (horizontal) and 6 mm (vertical). The diamond tip of the stylus has a radius generally of 2 μm at its end and a vertex angle of 90°. The static measurement force is less than 1 mN. The stylus instrument is directly tied to the basic metric unit using a standard calibration.

The inventive drum reduces the frequency of cleaning operations by limiting the picking of short fibres on the surface of the cylinder particularly in the event of it being used for wetlaid products, highly sensitive to this phenomenon and cuts down on short fibre loss when it is used, particularly in relation to wetlaid products.

The invention also targets, independently, a perforated metal cylinder intended for the production of patterned nonwoven textile products, characterised in that it is constituted by at least two layers whereof a first layer corresponds to a first level constituting at least one first lateral wall zone provided with through perforations defined by first full parts, and whereof at least one second layer corresponds to a second level constituting at least one second lateral wall zone provided with through perforations defined by second full parts.

The perforated patterning drum may be manufactured in two phases. In a first phase, nickel or another metal is deposited electrolytically by the silk-screen printing technique on a conductive die. A photographic film is made representing the design of the bottom perforations. This film is then laid on a die that has very exactly the inner diameter of the perforated cylinder. This die is previously coated with a photosensitive layer. After exposure to light radiation, the die is rinsed. Only the coated zones not exposed to the radiation remain on the die. This is then immersed in an electrolytic bath. The nickel or other metal is deposited on the zones not coated with a photosensitive layer. After about eight hours, the deposit has reached its optimum thickness. The cylinder is then removed from the mould. The cylinder is coated, once again, with a photosensitive layer. A new film representing the marking pattern is laid on the cylinder. This is then exposed to light radiation. The cylinder is rinsed. Only the areas of the coated layer not exposed to the radiation remain on the cylinder. This is immersed in an electrolytic bath. The nickel or other metal is deposited on the previously produced cylinder on the zones not covered with a photosensitive layer. The nickel or other metal does not fill the perforations of the lower cylinder. The perforations are therefore extended on the new deposit of nickel or other metal. After about 10 hours, the new deposit has reached its optimum thickness. The cylinder is then removed from the bath and cleared of photosensitive layer residues.

Another subject of the invention is a method for manufacturing a drum according to the invention wherein
a photographic film is made representing the design of the perforations,
the film is laid on a die having the internal diameter of the drum and coated with a photosensitive layer on some parts,
the die is exposed to light radiation such that only the coated parts not exposed to the radiation remain on the die,
metal is then deposited by electrolysis on the uncoated parts obtaining a lower cylinder that has perforations,
the lower cylinder is removed from the mould,
the lower cylinder is coated with a photosensitive layer on some zones,
another film representing the marking pattern is laid on the lower cylinder,
the lower cylinder is exposed to light radiation leaving only the unexposed zones of the coated layer on the cylinder, obtaining an exposed cylinder,
metal is deposited by electrolysis on the exposed cylinder, the metal being deposited on the zones not coated with the photosensitive layer without filling the perforations of the lower cylinder, obtaining a complete cylinder, and
the photosensitive layer residues are removed from the complete cylinder in order to obtain the drum.

Another purpose of the invention is a machine for producing a patterned nonwoven that includes water jet injectors on the outer face of the lateral surface of an inventive cylinder and means for passing a patternless lap between the cylinder and the injector. When emerging from the cylinder, the nonwoven lap is provided with a pattern conjugate with the cylinder pattern.

Nonwovens may comprise natural or artificial or synthetic fibres. Nonwovens are generally obtained by the technique of carding or aerodynamic carding; they may also comprise continuous thermoplastic filaments obtained by the so-called spunbonding technique, or even meltblowns. Nonwovens may also be obtained by so-called wetforming, and they may also be obtained by combining a number of methods, like, for example spunbonding plus carded webs, spunbonding plus natural yarn deposited aerodynamically by airforming and jet laced. Good results have been obtained with nonwovens of 30 to 150 g/m² based on viscose, viscose/polyester mixes and cotton. But this list is not restrictive. Nonwovens are generally between 0.5 mm and 2.5 mm thick, including the projecting patterns, and the projecting parts are preferably raised up by between 0.3 and 2.0 mm, and preferably between 0.5 and 1.5 mm. The thickness of the raised up parts is measured in the following way: the thickness is measured by placing the nonwoven in a device for measuring the thickness of nonwovens, as recommended by the standard EDANA ERT 30.5-99. The height of the raised up part is measured with an eight-power magnification micrometric scale magnifier. An eight-power magnification magnifier is also used to determine the distance over which the free ends of the filiform filaments project and the number thereof.

Nonwovens may be made subject to a first bonding treatment on a usual machine for hydroentangling nonwovens and immediately afterwards transferred continuously to the machine forming the subject matter of the present invention. But, and this is one of the advantages of the inventive machine, an unbonded lap can also be treated directly by the inventive machine for producing a patterned nonwoven, thereby simultaneously not only creating a pattern but also hydroentangling the nonwoven. The opportunity is therefore provided of producing a patterned nonwoven with less hydroentangling energy and less material without degrading its mechanical and visual properties.

To apply the treatment designed to implement the patterns, the jets of water may have a diameter of between 80 and 170 microns and preferably between 100 and 140 microns. The number of jets per metre is between 1,000 and 5,000 and preferably between 1,500 and 4,000. The water pressure in the injectors is between 10 and 400 bars and preferably between 80 and 250 bars. In general, a negative pressure is provided in the cylinder of between −20 mbars and −200 mbars and the drum is driven by customary rotary drive means at a speed of between 1 and 400 metres per minute.

The final object of the invention is a nonwoven which includes entangled filiform elements, in which a pattern is embossed, characterised in that the free ends (hairs) of the filiform elements project from the surface of the nonwoven that has the pattern over a length of less than 0.5 mm and the number of these projecting ends is less than 5/5 mm². The degree of hairiness of the nonwoven, patterned with the new drum, is less high than in the case of the prior art. This is explained by the fact that the new drum has a bonding surface that promotes the integration of the fibre ends in the fibrous mass.

The inventive nonwoven can be given without difficulty a pattern with continuous contours on one face. The dimension of the pattern along the face, as defined by the smallest imaginary inscribed circle, may be more than 2 mm and the pattern may have a uniform depth from 0.3 to 2 mm, and preferably from 0.5 to 1.5 mm. This opportunity for having a dimension of the pattern along the face, and therefore a radius of the pattern if it is circular or a length of the pattern if it is rectangular, of more than 2 mm enables not only patterns defined by lines to be obtained but also a pattern which is not defined by lines, the pattern being formed by the difference in level itself printed on the nonwoven and not only by contour lines printed on the nonwoven.

The inventive nonwoven can be used particularly as a cosmetic wipes, cleaning wipes or baby wipes.

Excellent results are obtained with a wetlaid sheet solely comprising cellulose fibres or a mixture of cellulose fibres and polyester fibres with a proportion of polyester fibres running up to 60% of the mass per unit area between 40 g/cm² and 120 g/cm². In this case, the fibre loss generated by the patterning method is small and below 5% of the total weight of the product since the water flow required for patterning is much smaller than the flows used in known hydraulic patterning technologies.

A preferred inventive nonwoven includes from 10 to 100% by weight of cellulose fibres or thermoplastic polymer filaments and preferably a mixture of the two, the mixture representing 100%.

In the appended drawings, given solely by way of example:

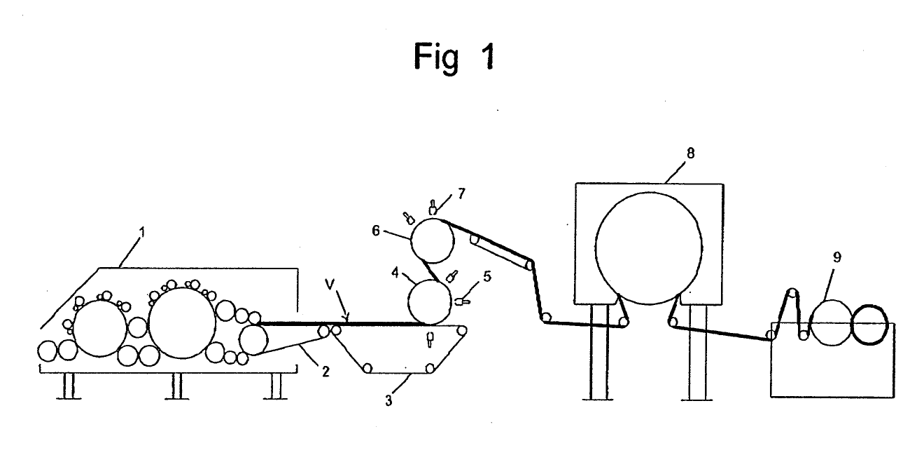

FIG. 1 is a diagrammatic view in elevation of a facility for producing a patterned nonwoven according to the invention;

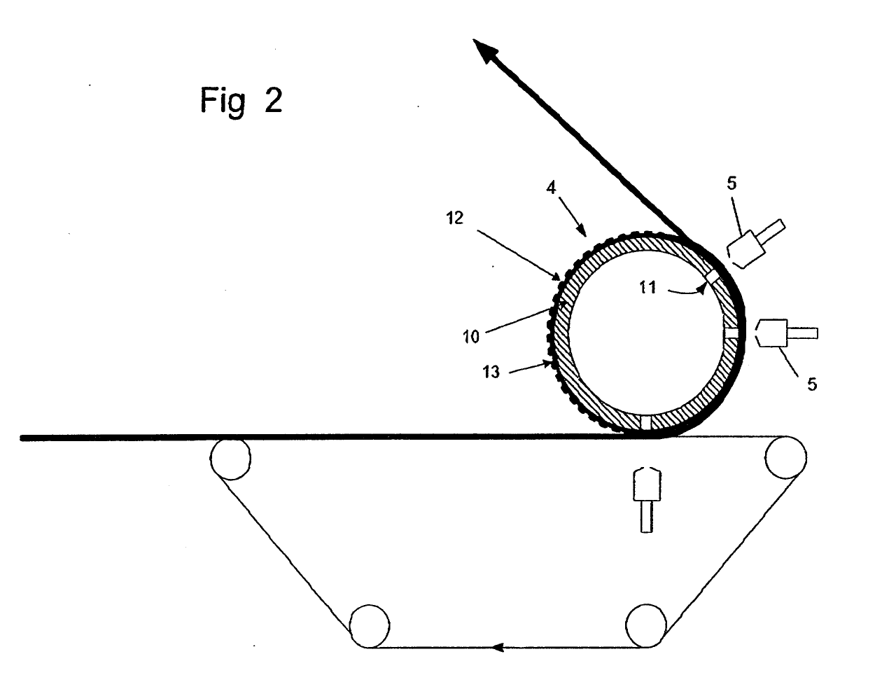

FIG. 2 is a cross-section view of the part comprising the inventive drum in FIG. 1;

FIG. 3 is a diagram illustrating the invention, FIG. 3a being a side view of the drum and injector unit, whereas FIG. 3b is an expanded view of the part surrounded by a circle in FIG. 3a;

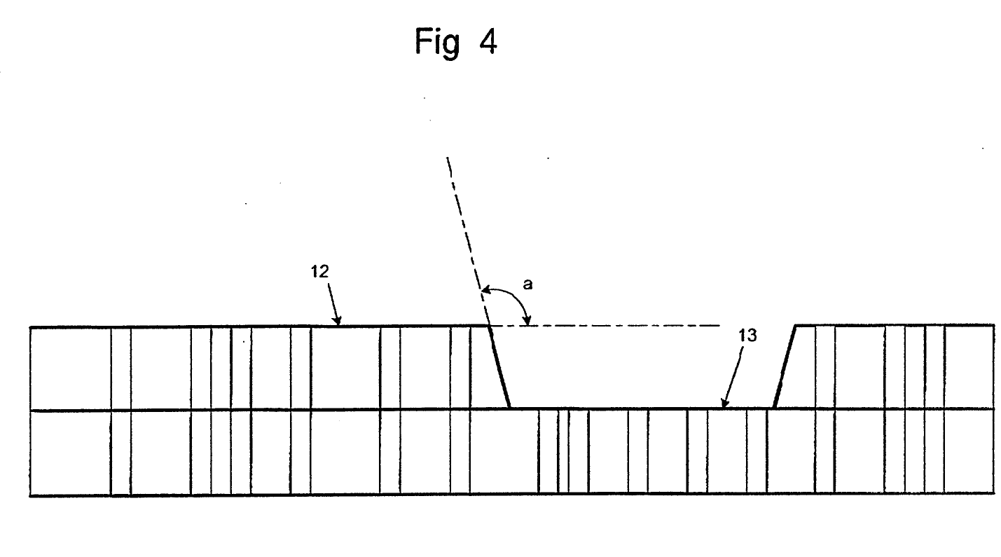

FIG. 4 is an expanded view of a part of the lateral surface of an inventive drum;

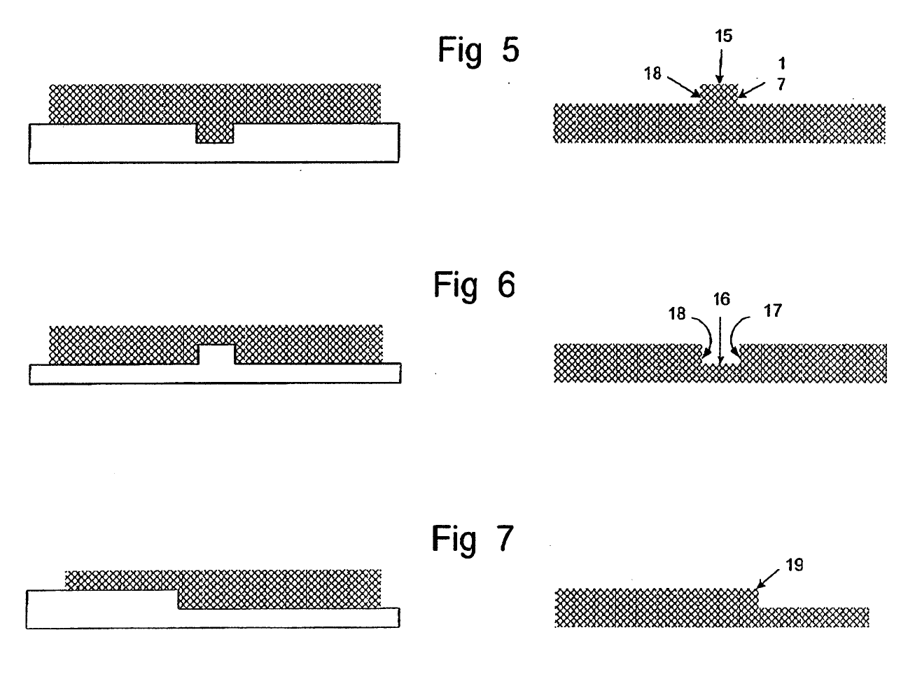

FIGS. 5, 6 and 7 show the formation of an embossed pattern and an intaglio pattern respectively.

The facility shown in FIG. 1 includes a system 1 for forming an unbonded nonwoven web V which emerges from the facility 1 via a conveyor 2 and passes on a conveyor 3 between the latter and a drum 4 constituted according to the invention. Facing the path followed by the web V on the drum 4 are placed two pressurised water jet injectors 5. The web V continues its path passing over a second inventive drum 6 fitted with injectors 7 before continuing its path towards a dryer 8 and a winder 9.

FIG. 2 shows the part of the facility shown in FIG. 1 essentially comprising the drum 4. The drum 4 is threaded onto a cylindrical, fixed, suction box 10, fitted with three suction slots 11 facing the injectors 5. The drum itself 4 includes projecting zones 12 and hollow zones 13 on the outer face of its lateral surface. The projecting zones 12 are at a higher level than the hollow zones 13, as considered along a radial direction of the drum. The drum is made of nickel. It comprises on one of the front edges a belt for rotating the drum using a motor. The inside of the suction box 10 is connected to a suction pump.

The composition of the drum can be seen more clearly in FIG. 3. It can be seen in particular that the drum is provided with perforations 14 both in the hollow zones 13 and in the projecting zone 12.

FIG. 4 shows that the angle a, between the outer lateral face of the lateral wall of the drum and the wall connecting a high level zone 12 to a low-level zone 13, is less than or equal to 96°, being greater than 90°.

FIGS. 5 and 6 show the creation of a projecting line 15 on the nonwoven in FIG. 5 and intaglio 16 on the nonwoven in FIG. 6.

FIG. 7 shows the formation of a large dimension pattern on the nonwoven which is not defined by lines with two substantially radial walls 17 and 18, as shown in FIGS. 5 and 6, but by a single contour wall 19.

The following examples illustrate the invention.

### EXAMPLE 1

A lap comprising (FIG. 2) 50% viscose fibres and 50% PET fibres of 55 g/m², pre-wet using the injector 5 to generate a curtain of water jets 140 μm in diameter spaced apart by 0.45 mm at a pressure of 15 bars and compacted between the porous conveyor cloth 2 and the micro-perforated patterning drum 4, advances at a speed of 50 metres per minute. Said lap is transferred directly to the patterning drum without pre-bonding. The drum has circular micro-perforations 0.3 mm in diameter and comprises 100 micro-perforations per cm. The patterning drum has a micro-perforated surface, as explained earlier on, and embossed. The distance between the high level and the low level of the drum surface is 1 mm. The high-level area to lower-level area ratio is 20%, thereby the pattern implemented is composed of patterns embossed on the drum and therefore intaglio on the product, after treatment by the injectors 5 and 5′ generating water jet curtains 120 μm in diameter and spaced apart by 0.6 mm respectively at a pressure of 50 and 100 bars.

The lap is then transferred on a suction carpet connected to a vacuum generator then dried at 150° C. in a draught furnace then wound in the form of a coil. A nonwoven is obtained that has an intaglio pattern over 20% of its surface and hairiness of 4 filiform elements per 5 mm² with a projection length of 0.5 mm².

### EXAMPLE 2

A lap of 60 g/m² constituted by a mixture of 40 mm long 1.7 dtex fibres made of 60/40 polypropylene/viscose advancing at 120 m/minute is pre-wet and compacted in a way similar to example 1 and transferred onto a micro-perforated bonding drum known in the prior art. On this drum the lap is bonded by two injectors, then transferred to the patterning drum, there being subjected to a treatment similar to that described in example 1. The patterning drum has a micro-perforated embossed surface. The distance between the high-level and the low level of the surface of the drum is 1.5 mm. The high-level area to low-level area ratio is 85%, the pattern implemented thereby comprising intaglio patterns on the drum and therefore embossed on the product. The nonwoven is obtained that has an embossed pattern over 15% of its surface with a hairiness rate of 3 filiform elements per 5 mm² with a projection length of 0.4 mm. This pattern is composed of 1 cm sided projecting squares.

1. Metal drum, having at a first level at least one first lateral wall zone provided with through perforations defined by first full parts and at least one second lateral wall zone provided with through perforations defined by second full parts at a second level different from the first level, characterised in that
the dimension of the perforations is between 0.1 and 1.2 mm,
the number of perforations both in the at least one first zone and in the at least one second zone is between 40 and 200 to the square centimetre, and
the opening ratio is between 3 and 60%.

2. Perforated metal drum intended for the production of patterned nonwoven textile products, characterised in that it is constituted by at least two layers whereof a first layer corresponds to a first level constituting at least one first lateral wall zone provided with through perforations defined by first full parts, and whereof at least one second layer corresponds to a second level constituting at least one second lateral wall zone provided with through perforations defined by second full parts.

3. Drum according to claim 2, characterised in that the dimension of the perforations is between 0.1 and 1.2 mm.

4. Drum according to claim 2, characterised in that the number of perforations both in the at least one first zone and in the at least one second zone is between 40 and 200 to the square centimetre.

5. Drum according to claim 2, characterised in that the opening ratio is between 3 and 60%.

6. Drum according to claim 1, characterised in that said first and second lateral wall zones each have an outer surface height and the variation in height of the outer surface heights of all the zones is less than 0.05 mm.

7. Drum according to claim 1, characterised in that it is made of nickel.

8. Drum according to claim 1, characterised in that the first and second lateral wall are integrally formed as one piece.

9. Drum according to claim 2, characterised in that the first layer is between 0.3 and 2 mm thick and the second layer is between 0.3 and 2 mm thick.

10. Drum according to claim 1, characterised in that it has several first lateral wall zones which are all at the same first level.

11. Drum according to claim 1, characterised in that it has several second lateral wall zones which are all at the same second level.

12. Drum according to claim 1, characterised in that the smallest imaginary inscribed circle, along the outer surface of the lateral wall, of a zone has a diameter of more than 0.5 mm.

13. Machine for producing a patterned nonwoven including an injector of water jets on the outer face of a lateral surface of a drum and means for passing a patternless lap (V) between the drum in front of the injector (5), characterised in that the drum is in accordance with claim 1.

14. Nonwoven which includes entangled filiform elements, in which a pattern is embossed, characterised in that the free ends of the filiform elements project from the face of the nonwoven with the pattern over a length of less than 0.5 mm and the number of these projecting ends is less than 5/5 mm².

15. Nonwoven that has on one face a continuous contour pattern in accordance with claim 14, characterised by a dimension of the pattern along the face, as defined by the smallest imaginary inscribed circle, of more than 2 mm, characterised by a uniform pattern depth of between 0.3 and 2 mm.

16. Nonwoven according to claim 14, including from 10 to 100% of cellulose fibres.

17. Nonwoven according to claim 14, including from 10 to 100% of continuous filaments of a thermoplastic polymer comprising a pattern.

18. Nonwoven according to claim 14, in the form of a baby wipe, a cosmetic wipe or a cleaning wipe.

19. Method for manufacturing a drum according to claim 1, characterised in that:
a photographic film is made representing the design of the perforations,
the film is laid on a die having the internal diameter of the drum and coated with a photosensitive layer on some parts,
the die is exposed to light radiation such that only the coated parts unexposed to radiation remain on the die,
metal is then deposited by electrolysis onto the uncoated parts obtaining a lower cylinder that has perforations,
the lower cylinder is removed from the mould,
the lower cylinder is coated with a photosensitive layer on some zones,
another film representing the marking pattern is laid on the lower cylinder,
the lower cylinder is exposed to light radiation leaving only the unexposed zones of the coated layer on the cylinder, obtaining an exposed cylinder,
metal is deposited by electrolysis on the exposed cylinder, the metal being deposited on the zones uncoated with the photosensitive layer without filling the perforations of the lower cylinder, obtaining a complete cylinder, and
the photosensitive layer residues are removed from the complete cylinder so as to obtain the drum.

20. Drum according to claim 1, characterised in that the opening ratio is between 5 and 15%.

21. Drum according to claim 1, characterised in that the smallest imaginary inscribed circle, along the outer surface of the lateral wall, of a zone has a diameter of more than 2 mm.

22. Drum according to claim 2, characterised in that the opening ratio is between 5 and 15%.

23. Drum according to claim 1, characterised in that said first and second lateral wall zones each have an outer surface height and the variation in height of the outer surface heights of all the zones is less than 0.05 mm, and the smallest imaginary inscribed circle, along the outer surface of the lateral wall, of a zone has a diameter of more than 0.5 mm.

24. Drum according to claim 23, characterised in that said drum includes several first lateral wall zones which are all at the same first level and several second lateral wall zones which are all at the same second level.

25. Drum according to claim 24, characterised in that the first and second lateral wall are integrally formed as one piece.
